(19) United States
(12) Patent Application Publication
(10) Pub. No.: US 2012/0227937 A1
(43) Pub. Date: Sep. 13, 2012

(54) HEAT DISSIPATION STRUCTURE FOR PHOTOVOLTAIC INVERTER

(75) Inventors: Numen Luo, New Taipei City (TW); Wess Juan, New Taipei City (TW)

(73) Assignee: ASIA VITAL COMPONENTS CO., LTD., New Taipei City (TW)

(21) Appl. No.: 13/045,793

(22) Filed: Mar. 11, 2011

(51) Int. Cl. H05K 7/20; F28D 15/04

(52) U.S. Cl. 165/104.26; 165/104.33

(57) ABSTRACT

A heat dissipation structure for photovoltaic inverter includes a photovoltaic inverter, a thermal module and at least one heat pipe. The thermal module has a heat dissipation backboard formed with at least one groove. The heat pipe is inlaid in the groove. The heat pipe has a plane face and an arcuate face. The plane face of the heat pipe is flush with the heat dissipation backboard and attached to the photovoltaic inverter. The arcuate face of the heat pipe is snugly attached to a wall of the groove. The processing cost and material cost of the heat dissipation structure are lowered and the heat dissipation efficiency of the heat dissipation structure is enhanced.

### FIELD OF THE INVENTION

The present invention relates to a heat dissipation structure for photovoltaic inverter, and more particularly to a heat dissipation structure applied to a photovoltaic inverter to save material, lower cost and enhance heat dissipation efficiency.

### BACKGROUND OF THE INVENTION

It is known that the energy sources of the earth have been nearly exhausted. Following the trend of environmental protection, renewable energies, such as solar energy, wind energy, tide energy, geothermal heat and biological waste energy, have become more and more respected. Such energies are renewable and reused without exhaustion.

In a current solar energy system, a solar module is used to generate power. The solar energy systems can be divided into stand-alone photovoltaic systems and grid-connected photovoltaic systems. The stand-alone photovoltaic system necessitates batteries for storing photovoltaic energy. The grid-connected photovoltaic system employs a grid-connected photovoltaic inverter for directly feeding photovoltaic energy into civil power network. That is, the grid-connected photovoltaic system is connected to the civil power network in parallel to feed the photovoltaic energy into the civil power network for the load terminals to use.

When using a photovoltaic inverter, the electronic components inside the photovoltaic inverter will generate heat. Therefore, a thermal module is needed to help in dissipating the heat so as to avoid deterioration of the efficiency or burnout of the electronic components due to too high temperature. The thermal module is generally made of metal material with high thermal conductivity. The thermal module is formed with radiating fins for increasing heat dissipation area. Also, in order to enhance heat dissipation effect, a cooperative cooling fan is used to forcedly dissipate the heat. Such thermal module is able to achieve the purpose of heat dissipation. However, the heat absorption capability of such thermal module is insufficient so that the heat dissipation efficiency is poor.

Please refer to FIGS. 1A and 1B. FIG. 1A is a perspective exploded view showing a conventional thermal module 10, while FIG. 1B is a sectional assembled view thereof. The thermal module 10 includes a heat dissipation substrate 11. The heat dissipation substrate 11 has a top section 111, a depression 112 and multiple circular grooves 113 on a first side. Multiple radiating fins 114 are formed on a second side of the heat dissipation substrate 11. The depression 112 is formed on the top of the circular grooves 113. A circular heat pipe 12 is disposed in each circular groove 113. A heat conduction board 13 is disposed in the depression 112. A first side of the heat conduction board 13 is attached to the circular heat pipes 12. A second side of the heat conduction board 13 is flush with the top section 111 to together form a plane face. A photovoltaic inverter 14 is attached to the plane face. The heat conduction board 13 serves to absorb the heat generated by the photovoltaic inverter 14. The circular heat pipes 12 serve to conduct the heat absorbed by the heat conduction board 13. However, the process for manufacturing and assembling the circular heat pipes 12 and the heat dissipation substrate 11 is complicated. As a result, the manufacturing cost is high and it is difficult to manufacture the thermal module.

Please refer to FIGS. 2A and 2B. FIG. 2A is a perspective exploded view showing another conventional thermal module 20, while FIG. 2B is a sectional assembled view thereof. The thermal module 20 includes a heat dissipation substrate 21. The heat dissipation substrate 21 has a top section 211, a depression 212 and multiple rectangular grooves 213 on a first side. Multiple radiating fins 214 are formed on a second side of the heat dissipation substrate 21. The depression 212 is formed on the top of the rectangular grooves 213. A flat heat pipe 22 is disposed in each rectangular groove 213. A heat conduction board 23 is disposed in the depression 212. A first side of the heat conduction board 23 is attached to the flat heat pipes 22. A second side of the heat conduction board 23 is flush with the top section 211 to together form a plane face. A photovoltaic inverter 24 is attached to the plane face. The heat conduction board 23 serves to absorb the heat generated by the photovoltaic inverter 24. The flat heat pipes 22 serve to conduct the heat absorbed by the heat conduction board 23. However, the space between the flat heat pipes 22 and the heat dissipation substrate 21 poses a thermal resistance to deteriorate the heat conduction effect between the flat heat pipes 22 and the heat dissipation substrate 21. As a result, the heat generated by the photovoltaic inverter 24 can be hardly conducted from the heat conduction board 23 to the flat heat pipes 22.

In both the above conventional thermal modules, the heat conduction boards are used as heat conduction media between the heat pipes and the heat sources. The material cost and processing cost of such conventional thermal modules are quite high. Moreover, the heat conduction effect provided by such conventional thermal modules is poor. Accordingly, the conventional thermal modules have the following shortcomings:

1. The manufacturing cost is high and the manufacturing process is complicated.
2. The material cost is high.
3. The heat conduction effect is poor.

### SUMMARY OF THE INVENTION

A primary object of the present invention is to provide a heat dissipation structure for photovoltaic inverter, which can conduct the heat generated by the photovoltaic inverter without any heat conduction medium. Therefore, the cost for the heat conduction medium is saved to lower the material cost.

A further object of the present invention is to provide the above heat dissipation structure for photovoltaic inverter. The processing cost of the heat dissipation structure is lowered to reduce manufacturing cost.

A still further object of the present invention is to provide the above heat dissipation structure for photovoltaic inverter, which is able to conduct heat at high heat conduction efficiency.

To achieve the above and other objects, the heat dissipation structure for photovoltaic inverter of the present invention includes a photovoltaic inverter, a thermal module and at least one heat pipe. The thermal module is disposed on a first side of the photovoltaic inverter. The thermal module has a heat dissipation backboard. The heat dissipation backboard has a top face and at least one groove. The top face of the heat dissipation backboard is attached to the photovoltaic inverter. The heat pipe is inlaid in the groove. The heat pipe has a plane face and an arcuate face. The plane face of the heat pipe is flush with the top face of the heat dissipation backboard and in contact with the photovoltaic inverter. The plane face of the heat pipe is directly attached to the photovoltaic inverter, whereby the heat generated by the photovoltaic inverter is directly absorbed by the plane face without any heat conduction medium. Therefore, the cost for the heat conduction medium is saved to lower the material cost. Moreover, the heat pipe is easily assembled with the heat dissipation backboard to lower the processing cost. In addition, the arcuate face of the heat pipe is snugly attached to a wall of the groove to effectively enhance heat dissipation efficiency. Therefore, the heat dissipation structure of the present invention has both the advantages of high performance and low cost.

### BRIEF DESCRIPTION OF THE DRAWINGS

The structure and the technical means adopted by the present invention to achieve the above and other objects can be best understood by referring to the following detailed description of the preferred embodiment and the accompanying drawings, wherein:

FIG. 1A is a perspective exploded view showing a conventional thermal module;

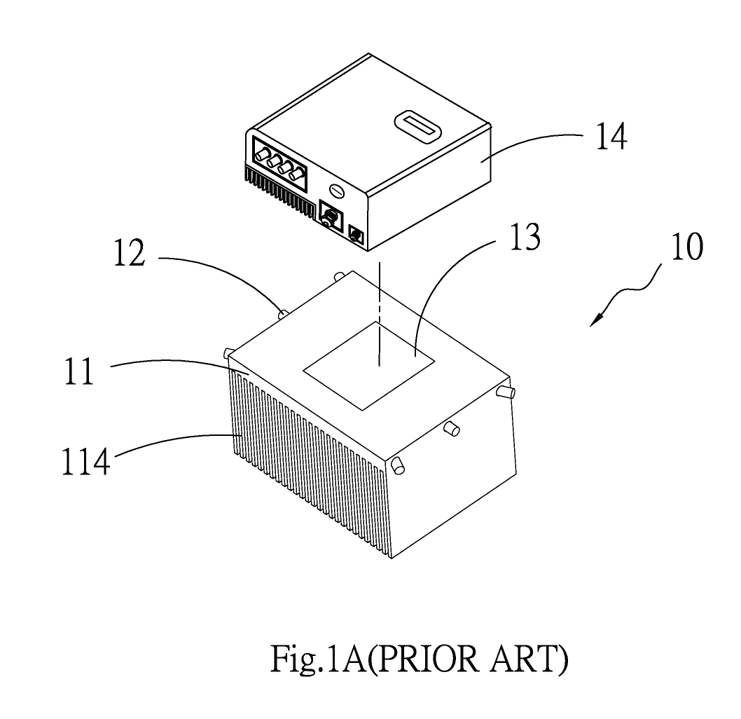

FIG. 1B is a sectional assembled view of the conventional thermal module of FIG. 1A;

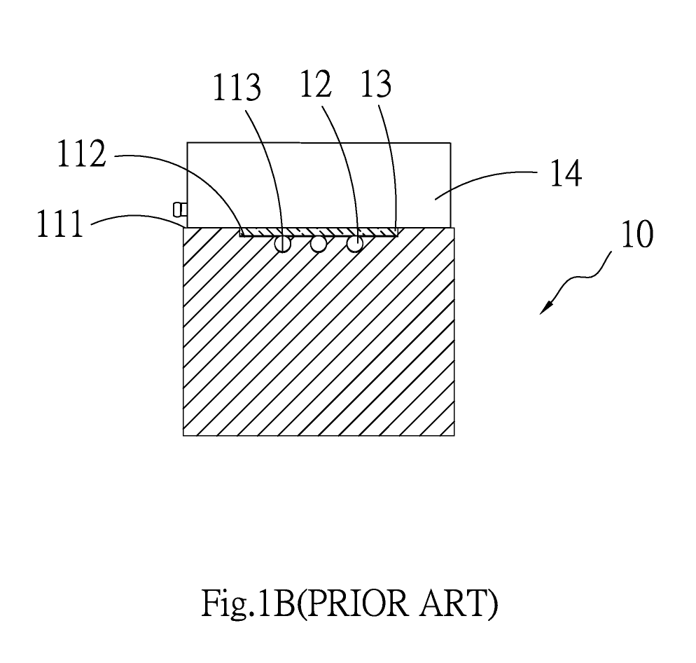

FIG. 2A is a perspective exploded view showing another conventional thermal module;

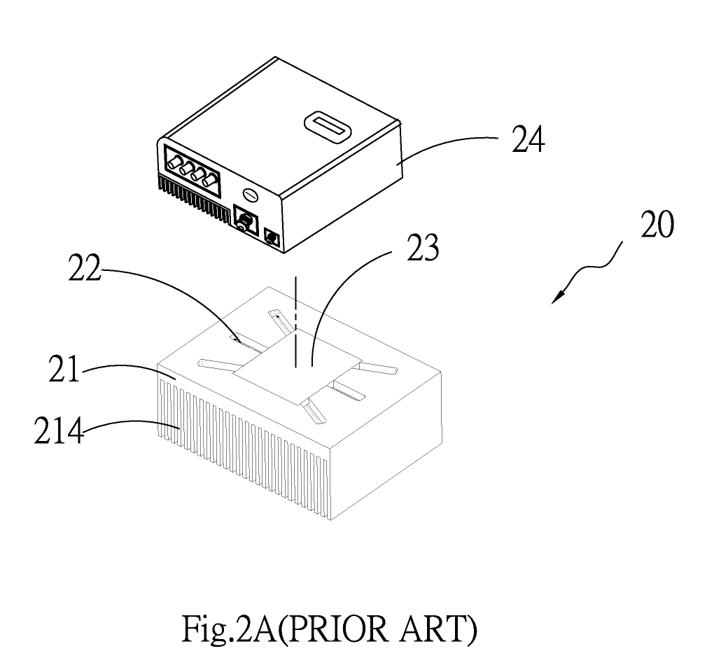

FIG. 2B is a sectional assembled view of the conventional thermal module of FIG. 2A;

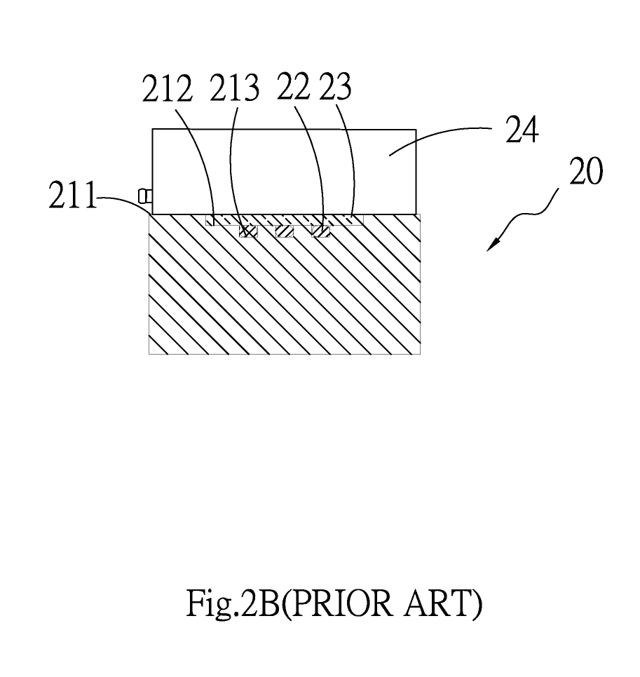

FIG. 3 is a perspective exploded view of a preferred embodiment of the present invention;

FIG. 4 is a perspective assembled view of the preferred embodiment of the present invention; and

FIG. 5 is a sectional assembled view of the preferred embodiment of the present invention.

### DETAILED DESCRIPTION OF THE PREFERRED EMBODIMENT

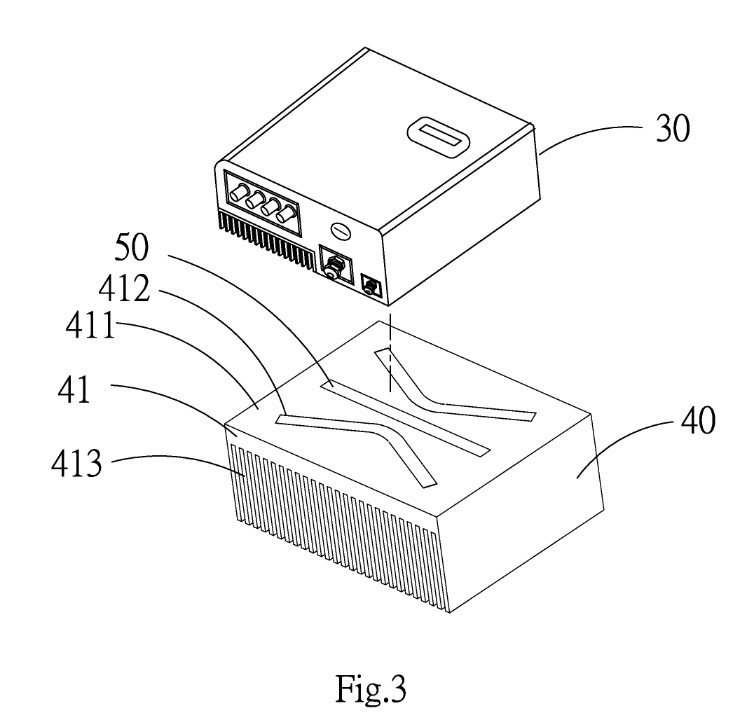

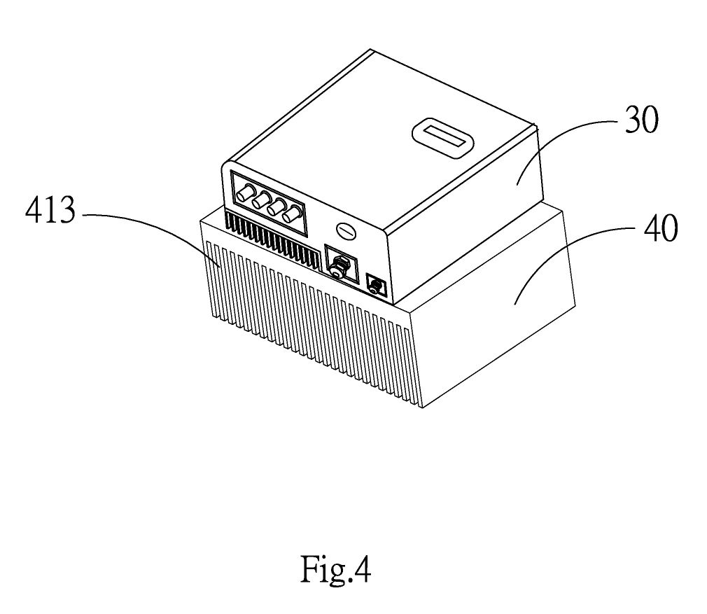

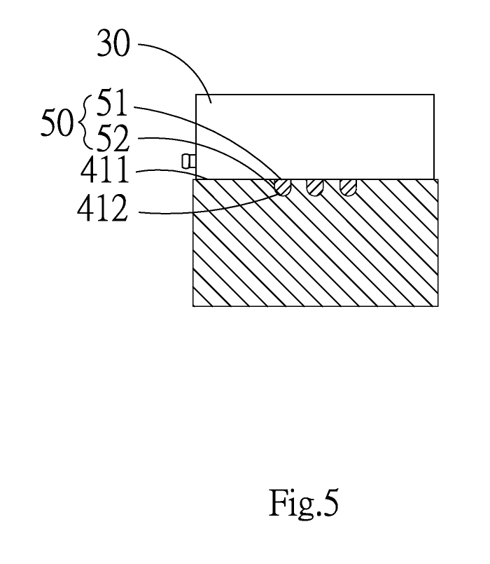

Please refer to FIGS. 3, 4 and 5. According to a preferred embodiment, the heat dissipation structure for photovoltaic inverter of the present invention includes a photovoltaic inverter 30, a thermal module 40 and at least one heat pipe 50. The photovoltaic inverter 30 is assembled with a first side of the thermal module 40. The thermal module 40 has a heat dissipation backboard 41. The heat dissipation backboard 41 has a plane top face 411 and multiple U-shaped grooves 412. Multiple radiating fins 413 perpendicularly extend from the other side of the heat dissipation backboard 41 opposite to the top face 411.

In this embodiment, the heat pipe 50 is selectively a D-shaped heat pipe 50. The heat pipe 50 has a plane top face 51 and an arcuate bottom face 52 in adjacency to the plane top face 51 to form the heat pipe 50.

The heat pipe 50 is inlaid in the groove 412. The arcuate bottom face 52 of the heat pipe 50 is snugly attached to the wall of the groove 412, while the plane top face 51 of the heat pipe 50 is flush with the top face 411 of the heat dissipation backboard 41. The photovoltaic inverter 30 is in contact with the plane top face 51 and the top face 411.

The heat generated by the photovoltaic inverter 30 is absorbed by the plane top face 51. During the heat conduction process, the heat absorbed by the plane top face 51 is first conducted from the arcutate bottom face 52 to the heat dissipation backboard 41 and then conducted to the radiating fins 413 to dissipate the heat. Accordingly, the thermal module 40 can dissipate the heat generated by the photovoltaic inverter 30.

The plane top face 51 of the heat pipe 50 is directly attached to the photovoltaic inverter 30. Therefore, the heat generated by the photovoltaic inverter 30 is directly absorbed by the plane top face 51 without any heat conduction medium between the photovoltaic inverter 30 and the plane top face 51. In this case, the cost for the heat conduction medium can be saved.

Moreover, the heat dissipation backboard 41 is formed with U-shaped groove 412 in which the heat pipe 50 is correspondingly inlaid. The U-shaped groove 412 is easy to process so that the processing cost is lowered. In addition, the heat pipe 50 is directly inlaid in the groove 412 so that the assembling cost is lowered to reduce manufacturing cost.

The heat pipe 50 is a D-shaped heat pipe. The arcuate bottom face 52 of the heat pipe 50 is snugly attached to the wall of the groove 412. Under such circumstance, no space exists between the heat pipe 50 and the heat dissipation backboard 41 so that no thermal resistance is posed between the heat pipe 50 and the heat dissipation backboard 41. In this case, the heat absorbed by the heat pipe 50 can be effectively conducted to the heat dissipation backboard 41.

Accordingly, the plane top face 51 of the heat pipe 50 is directly attached to the photovoltaic inverter 30 to directly conduct the heat generated by the photovoltaic inverter 30 without any heat conduction medium. Therefore, the cost for the heat conduction medium can be saved. Moreover, the heat pipe 50 is easily assembled with the heat dissipation backboard 41 to lower the processing cost and enhance heat dissipation efficiency. Therefore, the present invention has both the advantages of high performance and low cost.

The above embodiment is only used to illustrate the present invention, not intended to limit the scope thereof. It is understood that many changes and modifications of the above embodiment can be made without departing from the spirit of the present invention. The scope of the present invention is limited only by the appended claims.

What is claimed is:

1. A heat dissipation structure for photovoltaic inverter, comprising:
a photovoltaic inverter;
a thermal module disposed on a first side of the photovoltaic inverter, the thermal module having a heat dissipation backboard, the heat dissipation backboard having a top face and at least one groove; and
at least one heat pipe inlaid in the groove, the heat pipe having a plane face in contact with the photovoltaic inverter.

2. The heat dissipation structure for photovoltaic inverter as claimed in claim 1, wherein the heat pipe is inlaid in the groove with the plane face of the heat pipe flush with the top face of the heat dissipation backboard.

3. The heat dissipation structure for photovoltaic inverter as claimed in claim 1, wherein the top face of the heat dissipation backboard is in contact with the photovoltaic inverter.

4. The heat dissipation structure for photovoltaic inverter as claimed in claim 1, wherein the heat pipe is a D-shaped heat pipe having a plane top face as said plane face and an arcuate bottom face in adjacency to the plane top face.

5. The heat dissipation structure for photovoltaic inverter as claimed in claim 4, wherein the arcuate bottom face of the heat pipe is snugly attached to a wall of the groove.

6. The heat dissipation structure for photovoltaic inverter as claimed in claim 1, wherein multiple radiating fins perpendicularly extend from the other side of the heat dissipation backboard opposite to the top face.

7. The heat dissipation structure for photovoltaic inverter as claimed in claim 5, wherein the plane top face of the heat pipe is in direct contact with the photovoltaic inverter to directly absorb heat generated by the photovoltaic inverter, the heat absorbed by the plane top face being conducted from the arcuate bottom face to the heat dissipation backboard.
